(19) United States
(12) Patent Application Publication
(10) Pub. No.: US 2018/0188214 A1
(43) Pub. Date: Jul. 5, 2018

(54) Ultrasonic Probe and Ultrasonic Inspection Apparatus

(71) Applicant: Hitachi Power Solutions Co., Ltd., Hitachi-shi, lbaraki (JP)

(72) Inventors: Shigeru OONO, Ibaraki (JP); Kenta SUMIKAWA, Ibaraki (JP); Takuya TAKAHASHI, Ibaraki (JP); Takahiko YANAGITANI, Tokyo (JP)

(21) Appl. No.: 15/740,116

(22) PCT Filed: Jun. 21, 2016
(86) PCT No.: PCT/JP2016/068420

§ 371 Date: Dec. 27, 2017

(30) Foreign Application Priority Data
Jun. 30, 2015 (JP) 2015-130769

(51) Int. Cl. G01N 29/24; G01N 29/265; H01L 41/31

(52) U.S. Cl. CPC G01N 29/2437; H04R 17/00; H01L 41/31; G01N 29/265

(57) ABSTRACT

To easily form an ultrasonic probe and an ultrasonic inspection apparatus capable of sending ultrasonic waves having frequencies equal to or more than 200 MHz. In view of this, an ultrasonic probe includes a stacked piezoelectric element configuring an ultrasonic probe includes a stacked piezoelectric element in which a stacked piezoelectric film disposed between a lower electrode and an upper electrode. The stacked piezoelectric film includes a ZnO film that has spontaneous polarization in a direction substantially perpendicular to the film surface and a SLAIN film that is different from the ZnO and that has spontaneous polarization in the opposite direction to the ZnO, the SLAIN film being directly formed on the ZnO film.

### TECHNICAL FIELD

The present invention relates to an ultrasonic probe and an ultrasonic inspection apparatus.

### BACKGROUND ART

In recent years, consumer products such as cellular phones are required to become lighter, thinner, and shorter. Accordingly, the electronic components are subjected to miniaturization and the packages are also subjected to diversification and complication. To detect a crack, a separation, or a void (gap) inside these packages so as to ensure reliability, nondestructive inspection is performed with ultrasonic.

An ultrasonic inspection apparatus is used to perform the nondestructive inspection. In the ultrasonic inspection apparatus, a device which faces the inspection target to send and receive ultrasonic waves is called an ultrasonic probe. When radiated to the inspection target, ultrasonic waves are transmitted and reflected at the interface between the surface and the inside of the inspection target, and propagate inside the inspection target. The reflectance and the transmittance at each of the interfaces are different according to materials at the front and rear of the interface. The reflected waves from each of the interfaces return to the ultrasonic probe with delay corresponding to the distance from the ultrasonic probe and with magnitude according to the materials at the front and rear of the interface. Thus, by carrying out a work including sending ultrasonic waves, receiving ultrasonic waves returned a predetermined time later, and then displaying pixels having brightness corresponding to the reflection magnitude, with the ultrasonic probe scanning on the inspection target, a reflection magnitude distribution image for the inspection target interface in question can be obtained. For example, ultrasonic waves are reflected approximately 100% at void portions, so that clear difference from the periphery can be observed on the reflection magnitude distribution image. Thus, the void in the inspection target can be detected.

Due to development of electronic components which is to be the inspection targets, there have been demands for high-frequency type ultrasonic probes capable of detecting even smaller defects. Here, the high-frequency wave means an ultrasonic wave having a frequency, for example, equal to or more than 200 MHz.

Generally, the ultrasonic inspection is performed with the inspection target soaked in water where ultrasonic waves easily propagate. When using the higher-frequency waves, however, attenuation of the ultrasonic wave may be greater in the water or in the inspection target. Thus, it is necessary to increase the S/N ratio of the high-frequency ultrasonic wave. As for a method of increasing the S/N ratio, there is a method in which electrical impedance matching is performed between a sending and receiving measurement unit and a piezoelectric element in the ultrasonic probe.

The piezoelectric element has a structure in which piezoelectric material is held between electrodes. In an electricity circuit, the piezoelectric element can be treated similarly to the capacity element. In view of this, the impedance of the piezoelectric element is inversely proportional to the electrode area and is fairly proportional to the film thickness of the piezoelectric material. Therefore, the impedance can be increased by a method of reducing the electrode area or a method of increasing the film thickness. Here, performing impedance matching for piezoelectric elements of high-frequency type equal to or more than 200 MHz requires the electrode area to be reduced. However, this method is not realistic because radiation area of the ultrasonic wave becomes smaller. In the method of increasing the film thickness, the resonance frequency of the piezoelectric element is inversely proportional to the film thickness of the piezoelectric material, and thus oscillation of desired high-frequency waves cannot be implemented. As described above, there is a trade-off relationship between the frequency and the impedance matching with using the piezoelectric element of high-frequency type.

Patent Document 1 recites a method using higher mode resonance to avoid the problem of the trade-off relationship between the frequency and the impedance matching. Patent Document 1 shows a technique that a plurality of piezoelectric films having polarization directions being approximately parallel to the substrate and being opposite with each other are stacked, while each film having a thickness that enables obtaining the first mode resonance frequency, to thereby implement higher mode resonance corresponding to the stacking number.

### PRIOR ART DOCUMENT

### Patent Document

Patent Document 1: JP-2007-36915-A

### SUMMARY OF THE INVENTION

### Problem to be Solved by the Invention

The technique recited in Patent Document 1 uses the stacked piezoelectric film of the same materials having polarizations in respective opposite direction. When made to grow with the same materials, the piezoelectric films have a characteristic such that an underlayer having a polarization direction causes an upper layer disposed thereon to grow while the upper layer taking over the polarization direction of the underlayer. Thus, in growing the piezoelectric films having a polarization direction, it is extremely difficult to make the polarization direction change to the opposite direction on the way of the growing. In addition, the film formation speed of such stacked piezoelectric films is slow.

Although depending on the piezoelectric material, the piezoelectric substance with a resonance frequency equal to or more than 200 MHz has a film thickness of several micrometers. When higher mode resonance is used, the piezoelectric substances with several micrometers are required to be formed in a plural layers, which is difficult to be applied for a product if the growing speed of the layer is slow. In addition, it is conceivable to produce the piezoelectric film by laminating. However, similarly to the formation by the film formation, it is extremely difficult to laminate the piezoelectric substance having film thickness of several micrometers without generating cracks.

In view of this, it is an object of the present invention to easily form an ultrasonic probe and an ultrasonic inspection apparatus in which the impedance matching state is improved without decreasing the electrode area, and which can send ultrasonic waves whose frequencies are equal to or more than 200 MHz.

### Means for Solving the Problem

To solve the above-described problem, the ultrasonic probe of the present invention includes a piezoelectric element in which a stacked piezoelectric film is disposed between a lower electrode and an upper electrode. The stacked piezoelectric film is characterized in that a first piezoelectric layer is consisted of a first piezoelectric material which has a spontaneous polarization in a direction substantially perpendicular to a film surface; a second piezoelectric layer is consisted of a second piezoelectric material which is different from the first piezoelectric material and has a spontaneous polarization in an opposite direction to the first piezoelectric material, the second piezoelectric layer being directly formed on the first piezoelectric layer.

The other means will be described in embodiments for implementing the invention.

### Effect of the Invention

According to the present invention, an ultrasonic probe and an ultrasonic inspection apparatus are easily formed in which the impedance matching state is improved without decreasing the electrode area, and which can send ultrasonic waves whose frequencies are equal to or more than 200 MHz.

### BRIEF DESCRIPTION OF THE DRAWINGS

FIG. 1 is a perspective view illustrating an external appearance of a part of an ultrasonic inspection apparatus.

FIG. 2 is a schematic block diagram illustrating the ultrasonic inspection apparatus.

FIG. 3 is a cross-sectional view illustrating a configuration of the stacked piezoelectric element used for the ultrasonic probe in a first embodiment.

FIG. 4 is a cross-sectional view illustrating a configuration of the single-layer piezoelectric element using the ScAlN layer.

FIG. 5 is a cross-sectional view illustrating a configuration of the single-layer piezoelectric element using the ZnO layer.

FIG. 6 is a drawing illustrating measurement of the single-layer piezoelectric element.

FIG. 7 is a waveform drawing of electrical signals of the ScAlN layer and the ZnO layer.

FIG. 8 is a graph illustrating frequency characteristics of the single-layer piezoelectric element and the stacked piezoelectric element.

FIG. 9 is a cross-sectional view illustrating a configuration of the stacked piezoelectric element in a second embodiment.

FIG. 10 is a cross-sectional view illustrating a configuration of the stacked piezoelectric element in a third embodiment.

### MODES FOR CARRYING OUT THE INVENTION

Hereinafter, embodiments for implementing the present invention will be described in detail by referring to the drawings.

### First Embodiment

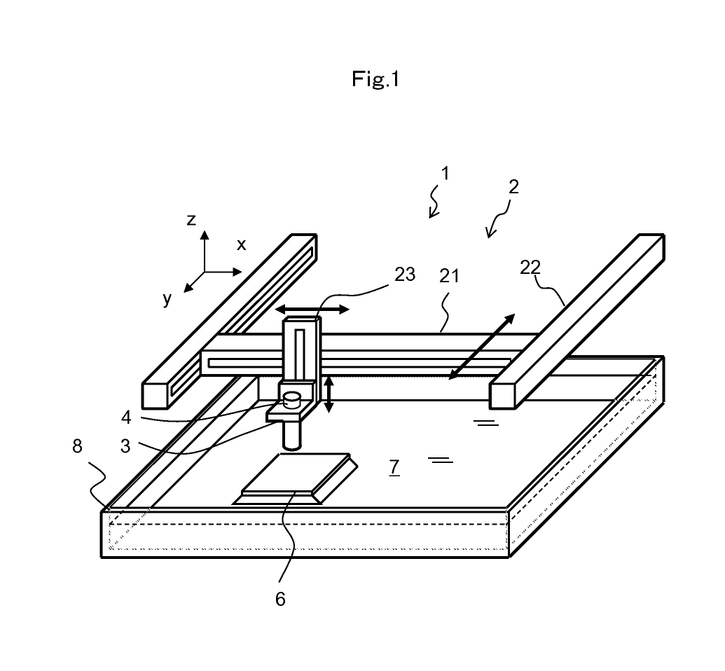

FIG. 1 is a perspective view illustrating an external appearance of the ultrasonic inspection apparatus 1.

The ultrasonic inspection apparatus 1 includes a three axis scanner 2 (scanning means), an ultrasonic probe 4, and a holder 3 holding the ultrasonic probe 4. The three axis scanner 2 is configured to include an x-axis scanner 21, a y-axis scanner 22, and a z-axis scanner 23. The z-axis scanner 23 is attached to the x-axis scanner 21, and the x-axis scanner 21 is attached to the y-axis scanner 22. The three axis scanner 2 adjusts the height of the ultrasonic probe 4 with respect to a planar inspection target 6 to scan the inspection target 6 in a two-dimensional manner. This allows the ultrasonic inspection apparatus 1 to visualize the planar inspection target 6 with the ultrasonic wave.

The ultrasonic probe 4 is attached to the three axis scanner 2 by the holder 3. The three axis scanner 2 scans the ultrasonic probe 4 in the two-dimensional manner and detects the scanning position. This allows the ultrasonic inspection apparatus 1 to visualize the relationship between each scanning position and the echo wave in the two-dimensional manner.

In addition, the inspection target 6 is disposed such that the inspection target 6 is soaked in a liquid medium 7 (generally, water), which is put into a water tank 8 to propagate ultrasonic waves, and the distal end of the ultrasonic probe 4 faces the inspection target 6.

Providing the water tank 8 a little larger than the operation ranges of the x-axis scanner 21 and the y-axis scanner 22 makes it possible for the ultrasonic probe 4 to scan on the inspection target 6 disposed at a given position in the water tank 8. The distance between the distal end of the ultrasonic probe 4 and the surface of the inspection target 6 can be freely adjusted with the z-axis scanner 23.

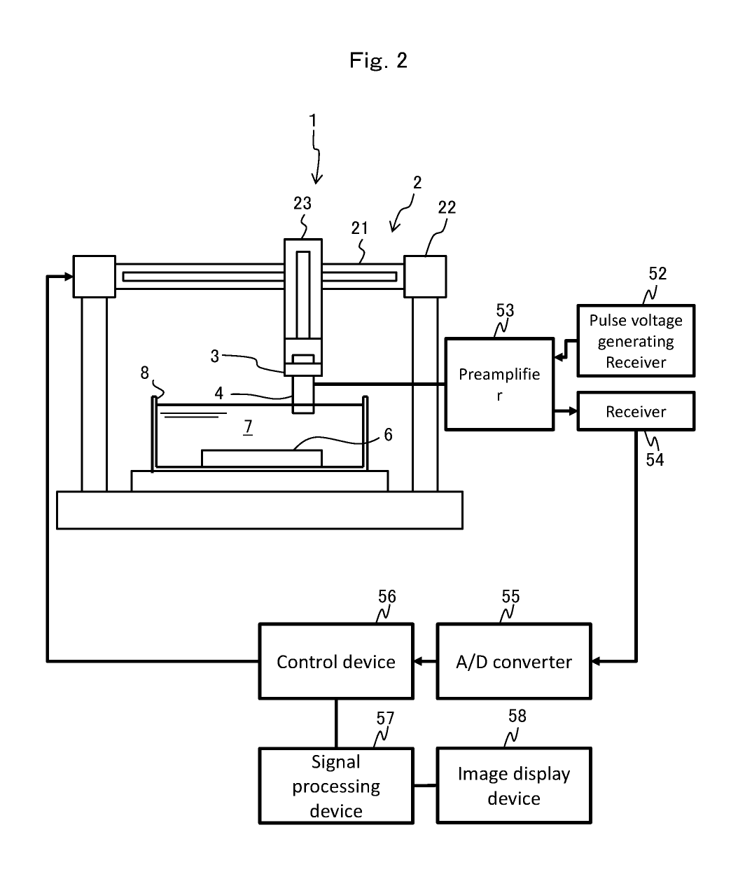

FIG. 2 is a schematic block diagram illustrating the ultrasonic inspection apparatus 1.

The ultrasonic inspection apparatus 1 is configured to include the ultrasonic probe 4, the three axis scanner 2, the holder 3, a pulse voltage generating device 52, a preamplifier 53, a receiver 54, an A/D converter 55, a control device 56, a signal processing device 57, and an image display device 58.

The pulse voltage generating device 52 outputs a signal at each predetermined scanning position. This signal is, for example, an electrical signal of the impulse wave or the burst wave.

The preamplifier 53 allows the ultrasonic probe 4 to output ultrasonic waves using the signal from the pulse voltage generating device 52. Then, the preamplifier 53 amplifies the signal received by the ultrasonic probe 4 and outputs it to the receiver 54. The receiver 54 further amplifies the input signal and outputs it to the A/D converter 55.

An echo wave reflected from the inspection target 6 is input to the A/D converter 55 through the receiver 54. The A/D converter 55 performs gate processing on the analogue signal of the echo wave to convert it into digital signal. Then, the A/D converter 55 outputs the digital signal to the control device 56.

The control device 56 controls this three axis scanner 2 to allow the ultrasonic probe 4 to scan in the two-dimension and measures the inspection target 6 with the ultrasonic wave while acquiring each scanning position of the ultrasonic probe 4. Supposing that the X-axis is a main scanning direction and the Y-axis is a sub scanning direction, for example, the control device 56 firstly moves the ultrasonic probe 4 to a starting-point position of the Y-axis. Next, the control device 56 moves the ultrasonic probe 4 in the main scanning direction and the forward direction to acquire the ultrasonic information on the odd number line, and then moves the ultrasonic probe 4 by one step in the sub scanning direction. Further, the control device 56 moves the ultrasonic probe 4 in the main scanning direction and the backward direction to acquire the ultrasonic information on the even number line, and then moves the ultrasonic probe 4 by one step in the sub scanning direction.

At each scanning position, a high-frequency signal is applied to the ultrasonic probe 4 from the pulse voltage generating device 52 through the preamplifier 53. By this high-frequency signal, the piezoelectric element in the ultrasonic probe 4 is deformed to generate ultrasonic wave, and the ultrasonic wave is sent from the distal end of the ultrasonic probe 4 to the inspection target 6.

A reflected wave returned from the inspection target 6 is converted to an electrical signal by the piezoelectric element in the ultrasonic probe 4 and amplified by the preamplifier 53 and the receiver 54. This amplified signal is converted to the digital signal at the A/D converter 55, and then subjected to pulse height analysis by the signal processing device 57. The signal processing device 57 displays a pixel having a contrast corresponding to the pulse height on the image display device 58.

To the signal processing device 57, each scanning position of the inspection target 6 and ultrasonic signals corresponding thereto are input from the control device 56. The signal processing device 57 performs processing to visualize the measurement result of the ultrasonic wave corresponding to each scanning position of the inspection target 6, and then displays the processed ultrasonic image of the inspection target 6 on the image display device 58.

While using the three axis scanner 2 to scan the ultrasonic probe 4, the control device 56 repeats a series of works to image a reflection magnitude distribution from the inside of the inspection target 6 on the image display device 58. By using this image, it is possible to detect a defect, such as a void, inside the inspection target 6.

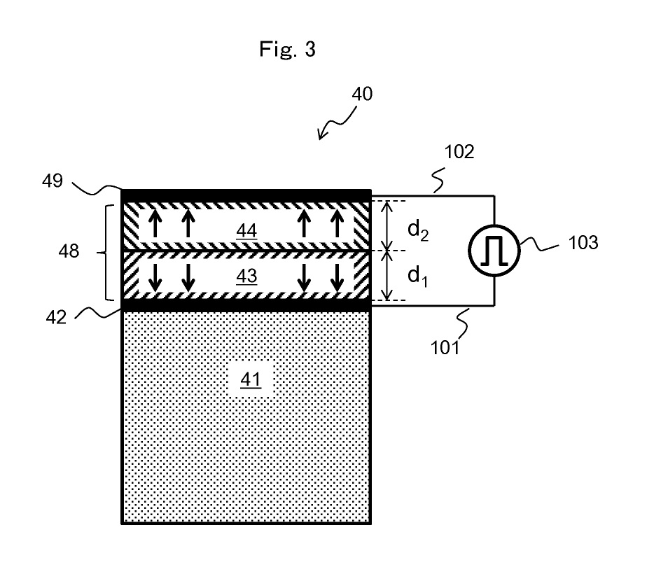

FIG. 3 is a cross-sectional view illustrating a configuration of the stacked piezoelectric element 40 used for the ultrasonic probe 4 in the first embodiment.

The ultrasonic probe 4 includes the stacked piezoelectric element 40 in which a stacked piezoelectric film 48 is disposed between the lower electrode 42 and the upper electrode 49. The stacked piezoelectric film 48 includes: a ZnO film 43 (first piezoelectric layer) having a c-axis whose direction is oriented to one direction approximately perpendicular to the surface of the piezoelectric thin film to have spontaneous polarization in which the upper surface side has O polarity; and a ScAlN film 44 (second piezoelectric layer) directly formed on the ZnO film 43, the ScAlN film 44 being consisted of ScAlN (second piezoelectric material), the ScAlN film 44 having a c-axis whose direction is oriented to one direction approximately perpendicular to the surface of the piezoelectric thin film to have spontaneous polarization in which the upper surface side opposite direction to the ZnO (first piezoelectric material) has Al polarity. It is noted that the direction of the spontaneous polarization approximately perpendicular to the stacked piezoelectric film means not only just 90 degrees, but also a substantially perpendicular direction, such as 70 degrees to 90 degrees with respect to the film surface, further preferably 80 degrees to 90 degrees. When the spontaneous polarization direction in the stacked piezoelectric film has local variation, the average polarization direction is used for the definition. In the above-described material, the c-axis direction is equal to the spontaneous polarization direction.

To prepare the stacked piezoelectric element 40, firstly the lower electrode 42 is formed on the substrate 41 of quartz glass further serving as the acoustic lens. On this lower electrode 42, the ZnO film 43 is formed that is a first piezoelectric layer having the spontaneous polarization. Then, on the ZnO film 43, the stacked piezoelectric film 48 is directly formed in which the ScAlN film 44 of the second piezoelectric layers is stacked, and further the upper electrode 49 is formed thereon. This ensures that the stacked piezoelectric element 40 is configured with the stacked piezoelectric film 48 held between the lower electrode 42 and the upper electrode 49. Because of this configuration, the upper surface of the ZnO film 43 has negative polarity and the upper surface of the ScAlN film 44 has positive polarity. In other words, two layers of the piezoelectric layers are formed to have reverse polarities for each other. As described above, different materials are stacked at each adjacent layer. Thus, it is easy to reverse the polarities of the piezoelectric layers of plural layers and to stack them.

Here, ScAlN is ScₓAl₁₋ₓN (x is more than 0 and less than 1), which is nitrogen compound in which scandium and aluminum are mixed at a predetermined ratio.

The methods for forming the lower electrode 42, the upper electrode 49, and the stacked piezoelectric film 48 are not particularly limited. Any of a spattering method, an evaporation method, a chemical vapor deposition (CVD) method and the like may be used. The ZnO film 43 has c-axis orientation in one direction (upper direction of FIG. 3) perpendicular to the surface of the thin film, and has spontaneous polarization in which the upper surface side has O polarity. The ScAlN film 44 has c-axis orientation, but has spontaneous polarization in which the upper surface side has Al polarity. Thus, the polarization direction is reversed. In FIG. 3, polarization direction is schematically shown by the arrow.

In the stacked piezoelectric element 40, the electricity cable 101 is coupled to the lower electrode 42 and the electricity cable 102 is coupled to the upper electrode 49, so that the voltage of the pulse power source 103 is applied. Thus, the stacked piezoelectric element 40 can generate ultrasonic waves.

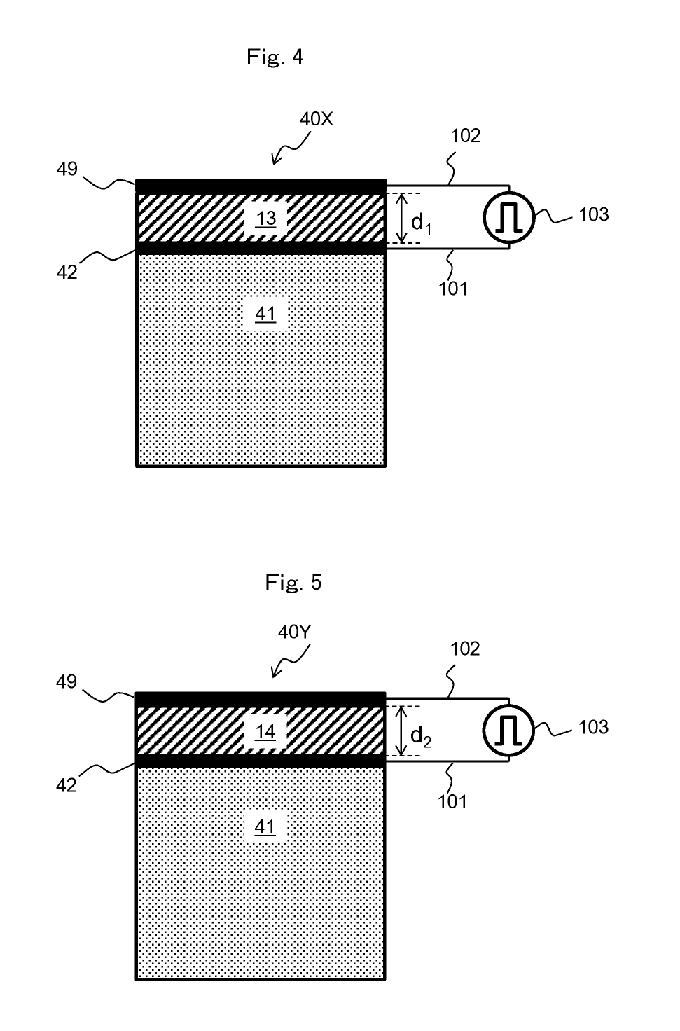

The experiment of the comparative example described below confirms that the polarities of the ZnO film 43 and the ScAlN film 44 are reversed. This experiment will be described with FIG. 4 to FIG. 7.

FIG. 4 is a view illustrating the single-layer piezoelectric element 40X which is a comparative example.

For preparing the single-layer piezoelectric element 40X, the lower electrode 42 is firstly formed on the quartz glass substrate 41. On this lower electrode 42, the ZnO film 13 is formed as a single film. Further, the upper electrode 49 is formed thereon. The electricity cable 101 is coupled to the lower electrode 42, the electricity cable 102 is coupled to the upper electrode 49, and the voltage of the pulse power source 103 is applied.

FIG. 5 is a view illustrating the single-layer piezoelectric element 40Y which is a comparative example.

For preparing the single-layer piezoelectric element 40Y, the lower electrode 42 is firstly formed on the quartz glass substrate 41. On this lower electrode 42, the ScAlN film 14 is formed as a single film. Further, the upper electrode 49 is formed thereon.

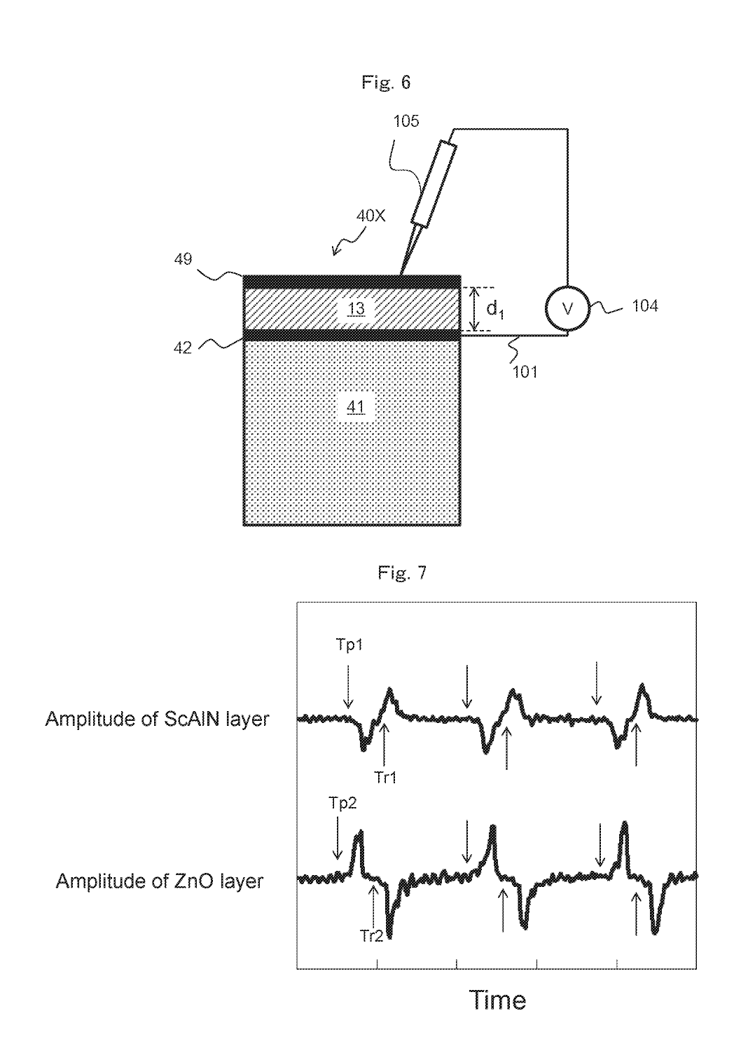

FIG. 6 is a view illustrating a measurement experiment of the single-layer piezoelectric element 40X.

In the measurement experiment illustrated in FIG. 6, the electricity cable 101 is coupled to the lower electrode 42 of the single-layer piezoelectric element 40X (see FIG. 4), and the probe 105 of the oscilloscope 104 is pushed thereon and released therefrom the upper electrode 49, so that the waveform generated at that time is measured. It is noted that the measurement can be similarly performed with respect to the single-layer piezoelectric element 40Y. Electrical signals at that time are illustrated in FIG. 7.

FIG. 7 is a waveform drawing of the electrical signals of the ScAlN layer and the ZnO layer.

The upper-side waveform represents a waveform at the time when the ScAlN single-layer piezoelectric element 40Y is measured. The time Tp1 represents the timing when the probe 105 is pushed thereon, and the time Tr1 represents the timing when the probe 105 is released therefrom. The ScAlN single-layer piezoelectric element 40Y generates negative voltage when pressure is applied, and generates positive voltage when the pressure is released.

The lower side waveform represents a waveform at the time when the ZnO single-layer piezoelectric element 40X is measured. The time Tp2 represents the timing when the probe 105 is pushed thereon, and the time Tr2 represents the timing when the probe 105 is released therefrom. The ZnO single-layer piezoelectric element 40X generates positive voltage when pressure is applied, and generates negative voltage when pressure is released. It can be confirmed by FIG. 7 that, with the probe 105 of the oscilloscope 104 being pushed and released, the polarities of the obtained electrical signals become reverse in cases between where materials configuring the piezoelectric layer is ZnO and where materials configuring the piezoelectric layer is ScAlN. By this result, it can be confirmed that the polarization directions of the ZnO film and the ScAlN film are opposite.

In the stacked piezoelectric element 40 illustrated in FIG. 3, the upper electrode 49 is formed on the stacked piezoelectric film 48 in which the ZnO films 43 and the ScAlN films 44 are alternately stacked, and thus the stacked piezoelectric film 48 is configured to be held between the lower electrode 42 and the upper electrode 49. The pulse voltage is applied to this stacked piezoelectric element 40 through the electricity cables 101, 102 by the pulse power source 103, and thus it is possible to send the ultrasonic wave from the stacked piezoelectric element 40.

At that time, in order to make the crystals of the ZnO film 43 and the ScAlN film 44 be subjected to the c-axis orientation perpendicularly to the substrate surface, the lower electrode 42 is preferred to be configured with the Au film that has smaller lattice distance to the ZnO film 43 and that is subjected to the [111]-axis orientation. Furthermore, it is better to have a metal film improving the adhesive characteristic of the Au film, for example, a layer of Ti, Cr, or the like, between the Au film and the substrate 41.

It is also possible to form the ScAlN film 44 on the lower electrode 42 and to stack the ZnO film 43 thereon. However, due to the relationship of film stress, when the film thickness is larger, the ScAlN film 44 separates easily. In case that the ScAlN film 44 is formed on the ZnO film 43, mitigation effect on the film stress is provided. Thus, it is preferred to form the ZnO film 43 on the lower electrode 42.

At that time, the film thickness d₁ of the ZnO film 43 and the film thickness d₂ of the ScAlN film 44 are preferred to be approximately equal to the first mode resonance frequency of the piezoelectric element consisted of the single-layer piezoelectric layer, the lower electrode 42, and the upper electrode 49. The relationship between the film thickness and the wavelength of the ultrasonic wave in the film would change according to the magnitudes of the acoustic impedances of the substrate 41 and the piezoelectric layer, which satisfies the condition represented by the below-described formula (1). Here, the λ₁ represents a wavelength of the ultrasonic wave inside the ZnO film 43, and the λ₂ represents a wavelength of the ultrasonic wave inside the ScAlN film 44. It is noted that, in practice, the film thicknesses d₁, d₂ may have approximately ±10% variations relative to the value calculated by formula (1), however, the variations are preferred to be approximately ±2%.

[Formula 1]

d₁=λ₁/2, d₂=λ₂/2 (1)

In addition, when sapphire is used as the substrate 41, the relationship between the film thickness and the wavelength of the ultrasonic wave in each film satisfies the condition represented by the below-described formula (2). In practice, the film thicknesses d₁, d₂ may have approximately ±10% variations relative to the value calculated by formula (2), however, the variations are preferred to be approximately ±2%.

[Formula 2]

d₁=λ₁/4, d₂=λ₂/4 (2)

When the structure satisfies formula (1) or formula (2), the frequency of the ultrasonic wave sent from the stacked piezoelectric element 40 becomes approximately equal to the frequency of the ultrasonic wave sent from the single-layer piezoelectric element 40X, 40Y and the film thickness of the piezoelectric substance can be thick.

Meanwhile, the stacked piezoelectric element 40 can increase the electrical impedance Z₃. This will be described with the below-described formula (3) to formula (5).

The electrical impedance Z₁ of the single-layer piezoelectric element 40X using the ZnO film 43 is represented by the below-described formula (3).

[Formula 3]

Z₁=d₁/(2πfϵ₁S) (3)

where f is a frequency of ultrasonic wave; S is an electrode area; and ϵ₁ is a dielectric constant of ZnO film.

The electrical impedance Z₂ of the single-layer piezoelectric element 40Y using the ScAlN film 44 is represented by the below-described formula (4).

[Formula 4]

Z₂=d₂/(2πfϵ₂S) (4)

where ϵ₂ is a dielectric constant of the ScAlN film.

On the other hand, the electrical impedance Z₃ of the stacked piezoelectric element 40 (see FIG. 3) is a sum of Z₁ and Z₂ as shown by the below-described formula (5), and thus can be increased more than the electrical impedances of the single-layer piezoelectric elements 40X, 40Y.

[Formula 5]

Z₃=(d₁/ϵ₁+d₂/ϵ₂)/(2πfS) (5)

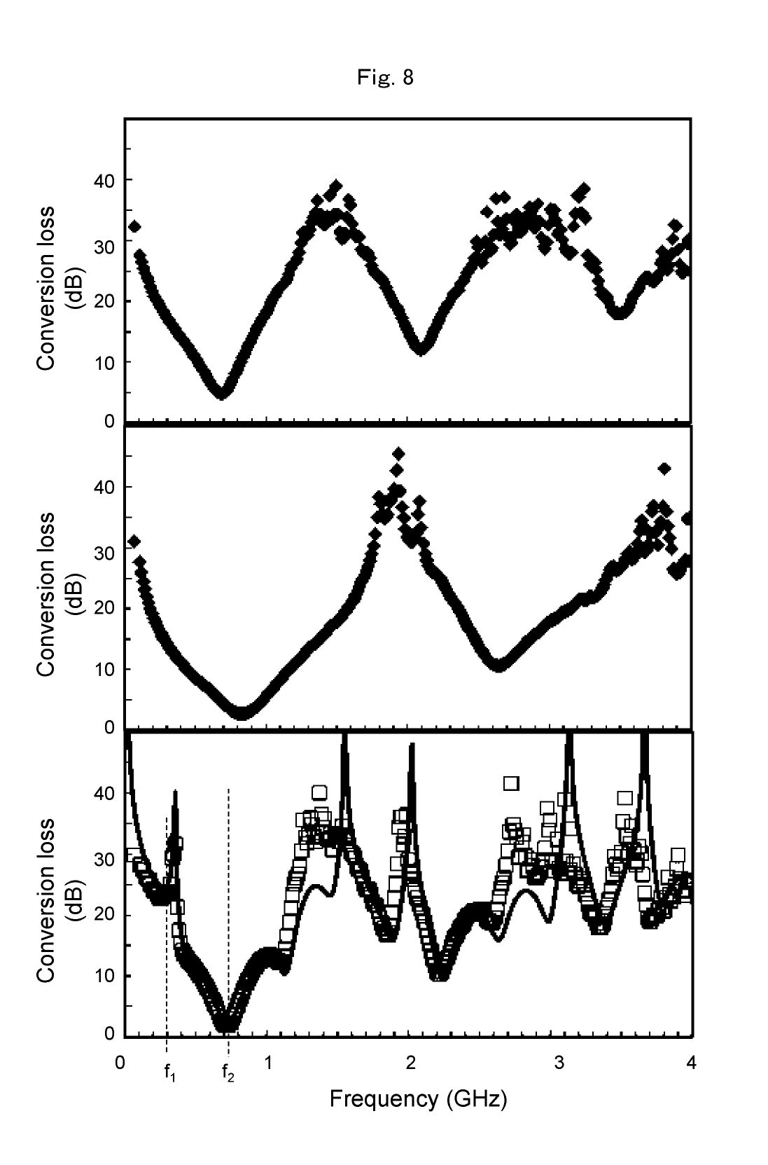

FIG. 8 is a graph illustrating a frequency characteristic of the conversion loss of the single-layer piezoelectric elements 40X, 40Y and the stacked piezoelectric element 40. The upper stage graph represents a frequency characteristic of the conversion loss of the single-layer piezoelectric element 40X. The middle stage graph represents a frequency characteristic of the conversion loss of the single-layer piezoelectric element 40Y, and the lower stage graph represents a frequency characteristic of the conversion loss of the stacked piezoelectric element 40. In FIG. 8, quartz glass is used as the substrate.

As represented by the upper stage graph, when the quartz glass is used as the substrate 41 and the single-layer ZnO film 43 (film thickness 4.2 μm) is used as the piezoelectric layer so as to form the single-layer piezoelectric element 40X (see FIG. 4), the basic resonance frequency becomes 683 MHz.

As represented by the middle stage graph, when the ScAlN film 44 (film thickness 3.9 μm) is used as the piezoelectric layer so as to form the single-layer piezoelectric element 40Y (see FIG. 5), the basic resonance frequency becomes 828 MHz.

In contrast, as represented by the lower stage graph, when 4.2 μm of the ZnO film 43 is stacked at the first layer from the substrate 41 side and 3.9 μm of the ScAlN film 44 is stacked at the second layer so as to form the stacked piezoelectric element 40 (see FIG. 3), the basic resonance frequency f₁ appears at approximately 300 MHz with a small magnitude and the second mode resonance occurs at 720 MHz (f₂). The magnitude of the second mode resonance of the stacked piezoelectric element 40 is larger than the basic mode of the piezoelectric element of the single-layer. Because of the configuration as described above, the electrical impedance can be increased by increasing the film thickness even with the same electrode area. Thus, it is possible to obtain a piezoelectric element with preferable electrical impedance, compared with the case of using the single-layer piezoelectric elements 40X, 40Y.

### Second Embodiment

In the first embodiment, a case is described where two layers of the piezoelectric layers are stacked. In the second embodiment, three layers of the piezoelectric layers are stacked.

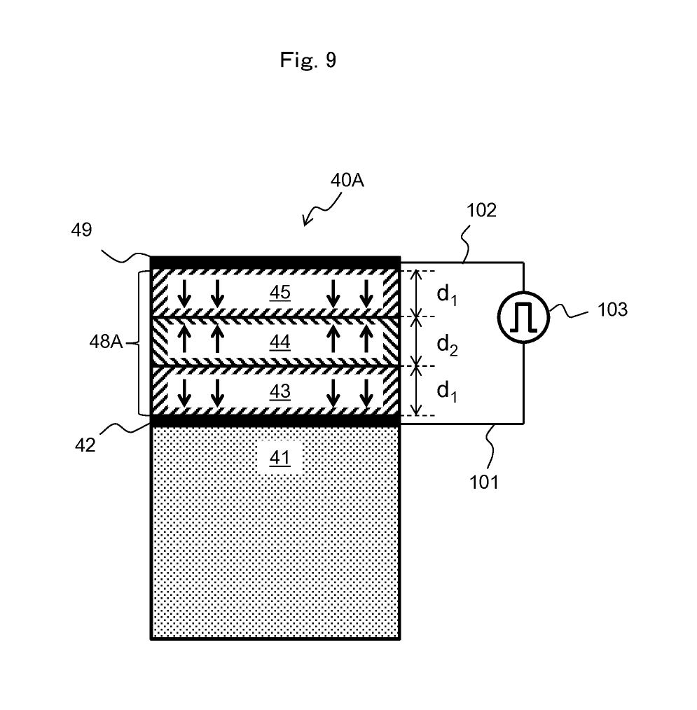

FIG. 9 is a cross-sectional view illustrating a configuration of the stacked piezoelectric element 40A in the second embodiment.

The stacked piezoelectric element 40A includes a stacked piezoelectric film 48A between the lower electrode 42 and the upper electrode 49. The stacked piezoelectric film 48A includes: a ZnO film 43 (first piezoelectric layer) having a c-axis whose direction is oriented in one direction approximately perpendicular to the surface of the piezoelectric thin film to have spontaneous polarization in which the upper surface side has O polarity; a ScAlN film (second piezoelectric layer) directly formed on the ZnO film 43, the ScAlN film 44 having a c-axis whose direction is oriented in one direction approximately perpendicular to the surface of the piezoelectric thin film to have spontaneous polarization in which the upper surface side has A1 polarity, opposite direction to the ZnO; and further a ZnO film 45 directly formed on the ScAlN film 44, the ZnO film having spontaneous polarization in which the orientation characteristic is approximately equal to and the polarity is equal to the ZnO film 43. In short, the piezoelectric layers consisted of ZnO and the piezoelectric layers consisted of ScAlN are alternately and plurally stacked.

Because of the stacked piezoelectric element 40A configured as described above, the third mode resonance occurs strongly at the frequency approximately equal to the case in which the single-layer piezoelectric elements 40X, 40Y are formed.

### Third Embodiment

In the third embodiment, furthermore, four layers of the piezoelectric layers are stacked.

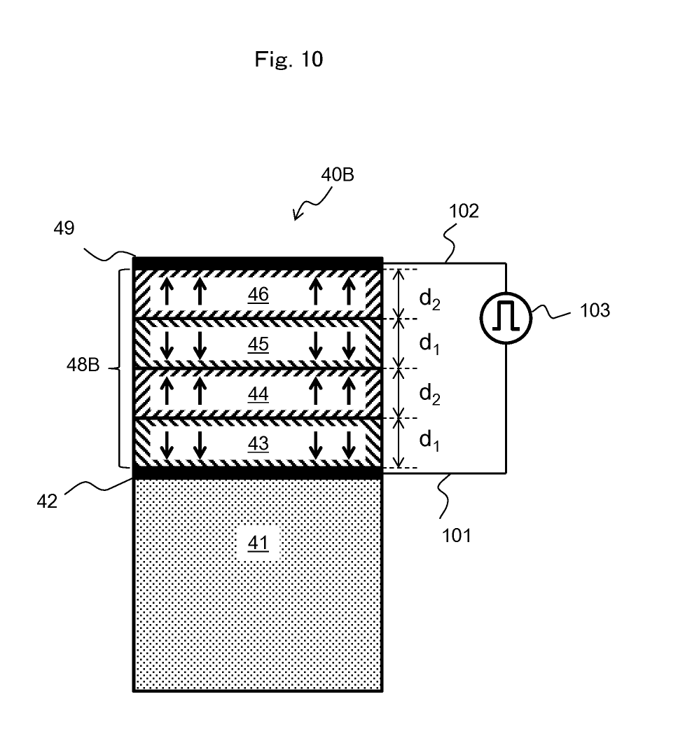

FIG. 10 is a cross-sectional view illustrating a configuration of the stacked piezoelectric element 40B in the third embodiment.

The stacked piezoelectric element 40B includes a stacked piezoelectric film 48B between the lower electrode 42 and the upper electrode 49. The stacked piezoelectric film 48B includes: a ZnO film 43 (first piezoelectric layer) having a c-axis whose direction is oriented in one direction approximately perpendicular to the surface of the piezoelectric thin film to have spontaneous polarization in which the upper surface side has O polarity; a ScAlN film (second piezoelectric layer) directly formed on the ZnO film 43, the ScAlN film 44 having a c-axis whose direction is oriented in one direction approximately perpendicular to the surface of the piezoelectric thin film and having spontaneous polarization in the opposite direction to the Zn0; a ZnO film 45 directly formed on the ScAlN film 44, the ZnO film 45 having spontaneous polarization in which the orientation characteristic approximately equal to and the polarity equal to the ZnO film 43; and further a ScAlN film 46 directly formed on the ZnO film 45, the ScAln film 46 having spontaneous polarization in which the orientation characteristic is approximately equal to and the polarity is equal to the ScAlN film 44. In short, the piezoelectric layers consisted of ZnO and the piezoelectric layers consisted of ScAlN are alternately and plurally stacked.

Because of the stacked piezoelectric element 40B configured as described above, the fourth mode resonance occurs strongly at the frequency approximately equal to the case in which the single-layer piezoelectric elements 40X, 40Y are formed.

Thereafter, similarly to the above, the ZnO films and the ScAlN films are alternately stacked to be n layers (n is a natural number equal to or more than two) to form the piezoelectric element, which allows nth mode resonance to strongly occur at the frequency approximately equal to the case where the single-layer piezoelectric element is formed. In this case, the electrical impedance is a sum of those of single-layers and it is possible to obtain a piezoelectric element with preferable electrical impedance.

In using the present invention, since each layer has reversed polarity, application of electric field in the same direction induces fundamental vibration of the layers and generates resonance having the order equal to the number of the layers. By stacking n layers for the piezoelectric layer, the stacked piezoelectric element has thicker film thickness. Since the electrical impedance is increased in comparison with the single-layer piezoelectric element, it induces advantages for the impedance matching, and the resonance frequency becomes approximately same as the single-layer piezoelectric element. Thus, the S/N ratio of the ultrasonic probe is improved.

In addition, the piezoelectric material is generally an insulator or a semiconductor, which is high-resistance material. When a high-frequency ultrasonic probe is produced with the single-layer piezoelectric element, the film thickness is decreased. Thus, dielectric breakdown or current leak occurs and then it easily causes the failure. However, in the stacked piezoelectric element the film thickness is thicker, and thus it is possible to increase the durability of the ultrasonic probe.

According to the present invention, the S/N ratio of the ultrasonic probe 4 is improved. Thus, when the ultrasonic probe 4 is used that is produced with the stacked piezoelectric element 40 of the present invention, it is possible to obtain an inspection image having high accuracy and high resolution.

### (Modification)

The present invention will not be limited to the above-described embodiments, and will contain various modifications. For example, the above-described embodiments will be written in detail for the explanation purpose, and the present invention will not be necessarily limited to what includes all the written configurations. A part of configurations of one embodiment may be replaced with a configuration of another embodiment, and a configuration of another embodiment may be added to configurations of one embodiment. In addition, a part of configurations of each embodiment may be also provided with another configuration, be deleted, or be replaced.

In each embodiment, the control line and the information line are provided for the explanation purpose, and thus not all the control lines and the information lines necessary for the product may be described. In fact, it can be thought that almost all of the configurations are coupled to each other.

Modifications of the present invention includes, for example, (a) and (b) described below.

(a) Instead of the ZnO film, CdS may be used as the first piezoelectric material to configure the first piezoelectric layer in which the c-axis direction is oriented in one direction approximately perpendicular to the surface of the piezoelectric thin film.

(b) Instead of the ScAlN film, any of AlN, GaN, and YbGaN may be used as the second piezoelectric material to configure the second piezoelectric layer.

### DESCRIPTION OF REFERENCE CHARACTERS

1: Ultrasonic inspection apparatus
2: Three axis scanner
3: Holder
4: Ultrasonic probe
40, 40A, 40B: Stacked piezoelectric element
40X, 40Y: Single-layer piezoelectric element
41: Substrate
42: Lower electrode
43, 45: ZnO film
44, 46: ScAlN film
48: Stacked piezoelectric film
49: Upper electrode
52: Pulse voltage generating device
53: Preamplifier
54: Receiver
55: A/D converter
56: Control device
57: Signal processing device
58: Image display device
6: Inspection target
7: Medium
8: Water tank
101, 102: Electricity cable
103: Pulse power source
104: Oscilloscope
105: Probe

1. An ultrasonic probe comprising:
a piezoelectric element in which a stacked piezoelectric film is disposed between a lower electrode and an upper electrode, wherein
the stacked piezoelectric film includes
a first piezoelectric layer made of a first piezoelectric material that has a spontaneous polarization substantially perpendicular to a surface of the film, and
a second piezoelectric layer made of a second piezoelectric material that is different from the first piezoelectric material and that has a spontaneous polarization in an opposite direction to that of the first piezoelectric material, the second piezoelectric layer being directly formed on the first piezoelectric layer.

2. The ultrasonic probe according to claim 1, wherein the stacked piezoelectric film is configured such that the first piezoelectric layer and the second piezoelectric layer are alternately and plurally stacked.

3. The ultrasonic probe according to claim 1, wherein
the first piezoelectric material configuring the first piezoelectric layer formed on the lower electrode is ZnO.

4. The ultrasonic probe according to claim 3, wherein the lower electrode is an Au film subjected to [111]-axis orientation.

5. The ultrasonic probe according to claim 1,
wherein
each of the first piezoelectric layers and each of the second piezoelectric layers have thicknesses capable of obtaining a first mode resonance, and
a resonance frequency of the first mode of each of the first piezoelectric layers and a resonance frequency of the first mode of each of the second piezoelectric layers are approximately equal to each other.

6. The ultrasonic probe according to claim 1, wherein
a thickness of each of the first piezoelectric layers is ¼ of a wavelength of an ultrasonic wave of the first piezoelectric material, and
a thickness of each of the second piezoelectric layers is ¼ of a wavelength of an ultrasonic wave of the second piezoelectric material.

7. The ultrasonic probe according to claim 1, wherein
a thickness of each of the first piezoelectric layers is ½ of a wavelength of an ultrasonic wave of the first piezoelectric material, and
a thickness of each of the second piezoelectric layers is ½ of a wavelength of an ultrasonic wave of the second piezoelectric material.

8. The ultrasonic probe according to claim 1, wherein
the second piezoelectric material is any of AlN, ScAlN, GaN, and YbGaN.

9. An ultrasonic inspection apparatus, comprising:
the ultrasonic probe according to claim 1.
